(19) United States
(12) Patent Application Publication
(10) Pub. No.: US 2008/0080252 A1
(43) Pub. Date: Apr. 3, 2008

(54) Methods of programming a memory cell and memory cell arrangements

(76) Inventors: Rainer Spielberg, Kirchheim (DE); Detlev Richter, Munich (DE)

Correspondence Address: SLATER & MATSIL LLP, 17950 PRESTON ROAD, SUITE 1000, DALLAS, TX, 75252, US

(21) Appl. No.: 11/541,401

(22) Filed: Sep. 29, 2006

(51) Int. Cl. G11C 11/34; G11C 16/04; G11C 16/06; G06F 12/00; G06F 13/28; G06F 13/00

(52) U.S. Cl. 365/185.22; 365/185.29; 711/103

(57) ABSTRACT

A method of programming a memory cell is provided that includes determining whether the memory cell has been neutralized in accordance with a predefined program neutralizing criterion. If the memory cell has not been neutralized in accordance with the predefined program neutralizing criterion, the memory cell is neutralized in accordance with a selected program neutralizing process. Furthermore, the method includes programming the memory cell.

### TECHNICAL FIELD

The invention relates to methods of programming a memory cell and memory cell arrangements.

### BACKGROUND

In programming memory cells, e.g. non-volatile memory cells, it should be provided that the data to be programmed is reliably programmed into the memory cells. Other features of non-volatile memory cells is the so-called retention time of a memory cell, i.e., the time period the memory cell stores a data item being written therein, and the so-called endurance, i.e., the time of the number of programming cycles the memory cell can be operated in a sufficiently reliable manner.

### SUMMARY OF THE INVENTION

In an embodiment of the invention, a method of programming a memory cell is provided that includes determining, whether the memory cell has been neutralized in accordance with a predefined program neutralizing criterion. If the memory cell has not been neutralized in accordance with the predefined program neutralizing criterion, the memory cell is neutralized in accordance with a selected program neutralizing process. Furthermore, the method includes programming the memory cell.

These and other features of embodiments of the invention will be better understood when taken in view of the following drawings and a detailed description.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1 shows a block diagram of an exemplary embodiment of a memory;

FIG. 2 shows a flowchart of the steps of an exemplary embodiment of a method of increasing the endurance of a non-volatile memory;

FIG. 3 shows a flowchart of an exemplary embodiment of a method of programming a non-volatile memory; and

FIG. 4 shows a flowchart of an exemplary embodiment of a program neutralizing process.

### DETAILED DESCRIPTION OF ILLUSTRATIVE EMBODIMENTS

As used herein the terms connected and coupled are intended to include both direct and indirect connection and coupling, respectively.

As used herein the term “program neutralizing” is intended to e.g., include any kind of process that is used to neutralize the effects of a program operation, in other words an operation to program a memory cell. In one embodiment of the invention, the term “program neutralizing” is intended to include e.g., an erase process, in which the logical state of one memory cell or a plurality of memory cells is changed, e.g., erased. Furthermore, the term “program neutralizing” is intended to include any kind of neutralizing process which may be used for neutralizing the effects of a program operation without changing the logical state (e.g., logic “0” or logic “1” in case of a single level cell; or e.g., logic “00”, logic “01”, logic “10”, logic “11” in case of a multi-level cell; etc.). In one embodiment of the invention, the term “program neutralizing” is intended to include any kind of process that is used to neutralize e.g., the effects of a program operation on one or more dielectric layers of one floating gate memory cell or a plurality of floating gate memory cells or e.g., the effects of a program operation on one or more dielectric layers of one charge-trapping memory cell or a plurality of charge-trapping memory cells, e.g., on its charge-trapping layer(s).

As used herein the term “multi-bit” memory cell is intended to e.g. include memory cells which are configured to store a plurality of bits by spatially separated electric charge storage regions, thereby representing a plurality of logic states.

As used herein the term “multi-level” memory cell is intended to e.g., include memory cells which are configured to store a plurality of bits by showing distinguishable threshold voltages dependent on the amount of electric charge stored in the memory cell, thereby representing a plurality of logic states.

In the context of this description, a “volatile memory cell” may be understood as a memory cell storing data, the data being refreshed during a power supply voltage of the memory system being active, in other words, in a state of the memory system, in which it is provided with power supply voltage. In contrast thereto, a “non-volatile memory cell” may be understood as a memory cell storing data, wherein the stored data is/are not refreshed during the power supply voltage of the memory system being active. However, a “non-volatile memory cell” in the context of this description includes a memory cell, the stored data of which may be refreshed after an interruption of the external power supply. As an example, the stored data may be refreshed during a boot process of the memory system after the memory system had been switched off or had been transferred to an energy deactivation mode for saving energy, in which mode at least some or most of the memory system components are deactivated. Furthermore, the stored data may be refreshed on a regular timely basis, but not, as with a “volatile memory cell” every few picoseconds or nanoseconds or milliseconds, but rather in a range of hours, days, weeks or months.

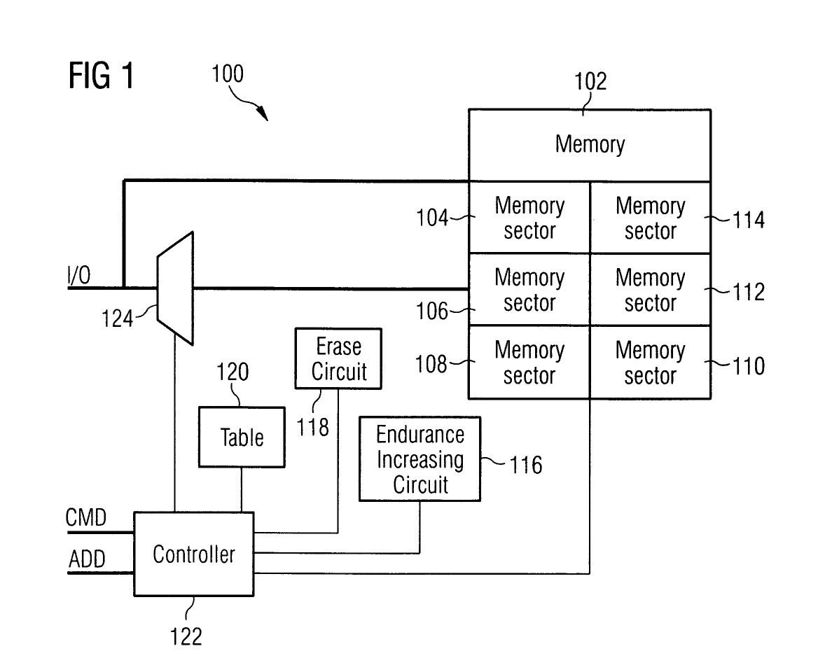

FIG. 1 shows a block diagram of an exemplary embodiment of a non-volatile memory cell arrangement 100.

Although the following embodiments describe non-volatile memory cell arrangements, the invention is also applicable to volatile memory cell arrangements. Furthermore, the invention is also applicable to floating gate memory cell arrangements as well as charge trapping memory cell arrangements.

In an embodiment of the invention, the charge trapping memory cell includes a charge trapping layer structure. The charge trapping layer structure includes a dielectric layer stack including at least two dielectric layers being formed above one another, wherein charge carriers can be trapped in at least one of the at least two dielectric layers. By way of example, the charge trapping layer structure includes a charge trapping layer, which may include or consist of one or more materials being selected from a group of materials that consists of: aluminum oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). In one embodiment of the invention, the charge trapping layer structure includes a dielectric layer stack including three dielectric layers being formed above one another, e.g. a first oxide layer (e.g. silicon oxide), a nitride layer as charge trapping layer (e.g. silicon nitride) on the first oxide layer, and a second oxide layer (e.g. silicon oxide or aluminum oxide) on the nitride layer. This type of dielectric layer stack is also referred to as ONO layer stack. In an alternative embodiment of the invention, the charge trapping layer structure includes two, four or even more dielectric layers being formed above one another. On the patterned charge storage layer structure, a control gate layer is provided, e.g., made of polysilicon or a metal such as copper or aluminum.

The non-volatile memory cell arrangement 100 includes one or more non-volatile memories 102 having a plurality of memory cell sectors 104, 106, 108, 110, 112 and 114. Each memory cell sector 104, 106, 108, 110, 112 and 114 has a plurality of non-volatile memory cells, each memory cell storing one or a plurality of data items, e.g., one or a plurality of bits. Only six memory cell sectors 104, 106, 108, 110, 112, and 114 are shown for illustrative purposes. The non-volatile memory cell arrangement 100 may include an arbitrary number of memory cell sectors, and each memory cell sector may include an arbitrary number of memory cells. In one embodiment of the invention, a memory cell sector 104, 106, 108, 110, 112 and 114 includes a number of memory cells, which are erased simultaneously (also referred to as erase sectors). However, any other kind of grouping the memory cells to groups may be provided in an alternative embodiment of the invention. The non-volatile memory cell arrangement 100 further includes an erase circuit 118 implementing a default erase method to erase the memory cells of the plurality of memory cell sectors 104, 106, 108, 110, 112 and 114 in a conventional manner. After a memory cell sector 104, 106, 108, 110, 112 and 114 has been erased a certain number of times, the retention and reliability of memory cells of the memory cell sector 104, 106, 108, 110, 112 and 114 degrades to or near an unacceptable level.

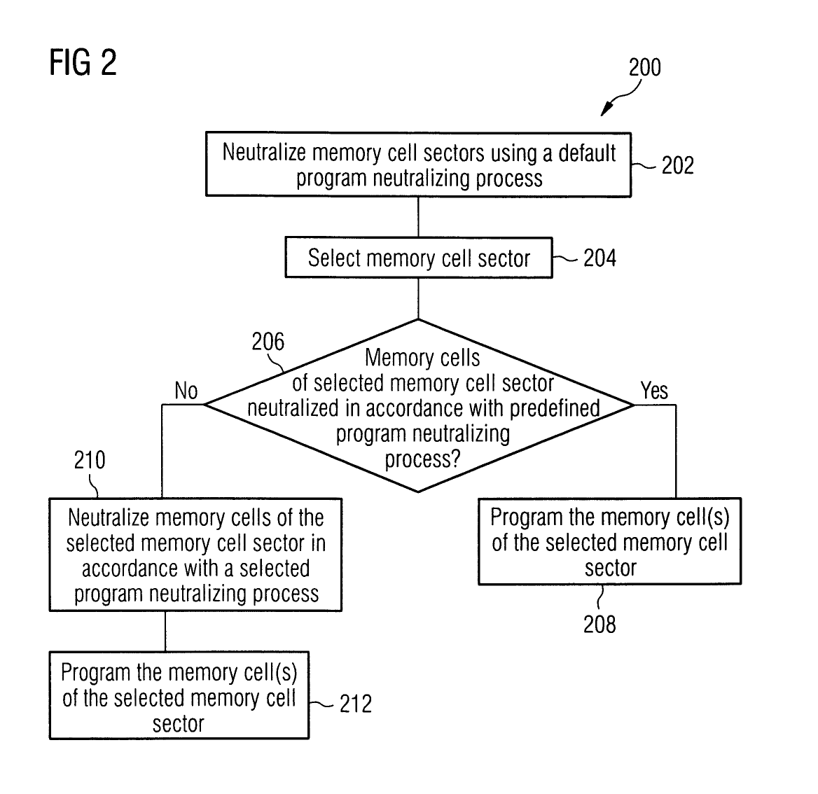

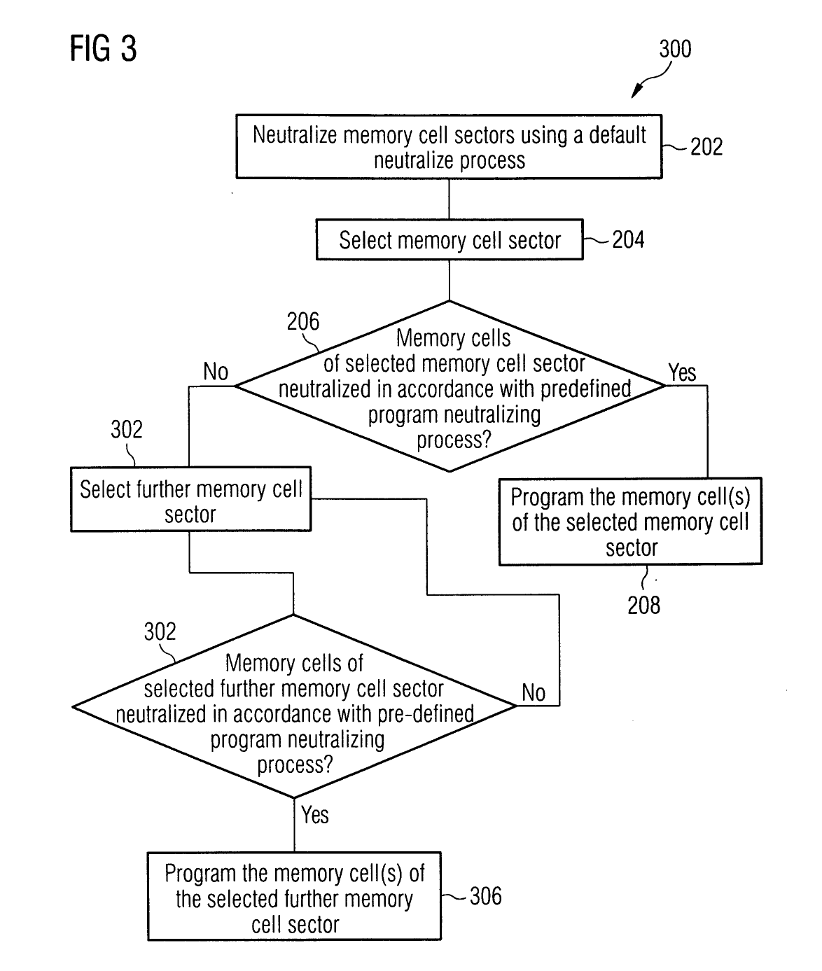

The non-volatile memory cell arrangement 100 further includes an endurance increasing circuit 116 increasing the endurance of the memory cell of the memory 102 by applying a plurality of different types of trap-neutralizing methods to the plurality of memory cell sector 104, 106, 108, 110, 112 and 114 of the memory 102. Applying the different types of trap-neutralizing methods to the plurality of memory cell sector 104, 106, 108, 110, 112 and 114 will be described in more detail below with reference to FIG. 2 and FIG. 3.

For example, consider an NROM (nitride read only memory) as an example of a charge trapping memory cell arrangement having a plurality of memory cell sectors included in different multilevel data storage capability quality class segments.

Consider multilevel data storage capability quality class segments of memory cells having a data storage capability of 1 bit/cell, 2 bits/cell, 4 bits/cell, and 6 bits/cell, for example.

A trap neutralizing process used for the memory cell sectors in the 1 bit/cell multilevel data storage capability quality class segment could be a fast single pulse HH (hot hole) erase. Furthermore, a PAE (program after erase) could then be performed on these memory cell sectors.

A trap neutralizing process used for the memory cell sectors in the 2 bit/cell multilevel data storage capability quality class segment could be a two pulse HH (hot hole) erase with sparse PBE (program before erase). A PAE (program after erase) could then be performed on these memory cell sectors.

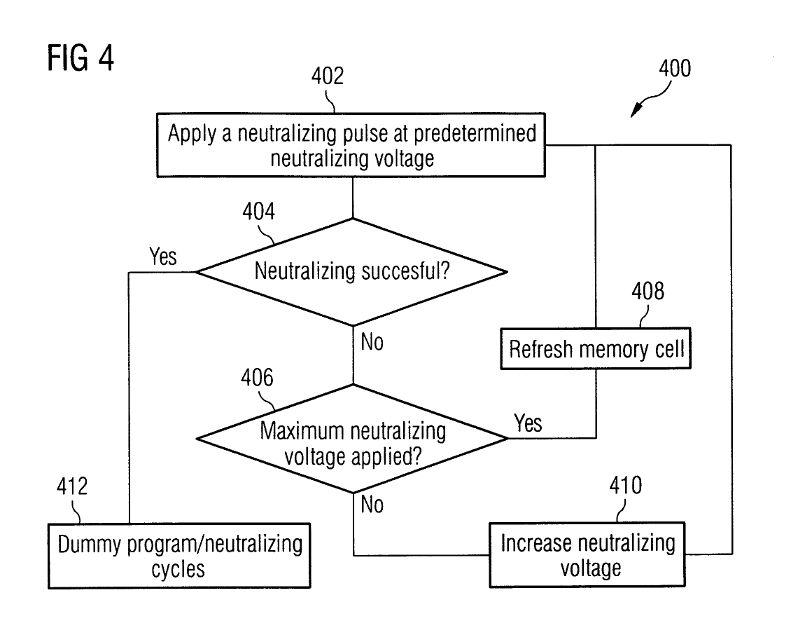

A trap neutralizing process used for the memory cell sectors in the 4 bit/cell multilevel data storage capability quality class segment could be an electrical program neutralizing method that will be described in more detail below with reference to FIG. 4.

A program neutralizing sector table 120 keeps track of which type of the plurality of trap-neutralizing methods, which will be described in more detail below, is applied to each one of the plurality of memory cell sectors 104, 106, 108, 110, 112 and 114. For example, if a fast single pulse hot-hole erase is applied to a first memory cell sector 104, an assigned flag can be set in the program neutralizing sector table 120 indicating that this type of trap-neutralizing method has been applied to the first memory cell sector 104. The program neutralizing sector table 120 can be implemented in the memory 102 as a separate memory region or may be implemented in a separate non-volatile memory.

A controller 122 can be configured to check the program neutralizing sector table 120 to insure that an acceptable type of the plurality of trap-neutralizing methods has been applied to a particular one of the plurality of memory cell sectors 104, 106, 108, 110, 112 and 114 before the particular one of the plurality of memory cell sectors 104, 106, 108, 110, 112 and 114 is programmed.

For example, suppose that the traps in the memory cells of the first memory cell sector 104 can be neutralized by performing a fast single pulse hot-hole erase or by performing another one of the plurality of types of trap-neutralizing methods. Before the first memory cell sector 104 is programmed, the controller 122 can check the program neutralizing sector table 120 to determine whether the fast single pulse hot-hole erase or another trap-neutralizing method has been performed on the first memory cell sector 104. If a trap-neutralizing method has been performed on the first memory cell sector 104 with acceptable success (which may be represented by the information about which trap-neutralizing method (in general, which program neutralizing method) has been carried out on the memory cells of the first memory cell sector 104), the controller 122 can then program the memory cell or the memory cells of the first memory cell sector 104 since the endurance of the memory cells of the first memory cell sector 104 has been suitably increased by the acceptable trap-neutralizing method.

Additionally or alternatively, the controller 122 can be configured to search the erase sector table 120 to find one of the plurality of memory cell sectors 104, 106, 108, 110, 112 and 114 having memory cells having an acceptable type of the plurality of trap-neutralizing methods applied thereto. Once a memory cell sector 104, 106, 108, 110, 112 and 114 has been found with the required quality, the memory cells of which have had an acceptable type of the plurality of trap-neutralizing methods applied thereto, the memory cell sectors 104, 106, 108, 110, 112 and 114 can be programmed since the endurance of the memory cell sector 104, 106, 108, 110, 112 and 114 has been suitably increased by the acceptable trap-neutralizing method. The controller 122 obtains command signals via a command interface CMD and address signals via an address interface ADD for controlling the memory 102. A multiplexer 124 is provided to selectively output signals from the memory 102 or the controller 122 to the I/O port 10 of the non-volatile memory cell arrangement 100.

In alternative embodiment of the invention, the functionality of the erase circuit 118 and the endurance increasing circuit 116 may be integrated into the controller 122 by means of corresponding computer programs.

FIG. 2 shows a flowchart of an exemplary embodiment of a method 200 of programming a non-volatile memory, which shows an increased endurance compared to the conventional method.

At 202, a default erase process is used to erase memory cell sectors 104, 106, 108, 110, 112 and 114. This default erase procedure can be a conventional erase procedure chosen depending on the particular type of memory cells used to construct the non-volatile memory cell arrangement 100. After a certain number of cycles of repeatedly erasing and programming the memory cells of the memory cell sectors 104, 106, 108, 110, 112 and 114 of the non-volatile memory cell arrangement 100, the memory cells become poor with respect to their reliability and retention. A cause of the limited endurance is charge trapped in the memory cells. The endurance of the memory cells of the non-volatile memory cell arrangement 100 can be increased by applying a suitable trap neutralizing method or procedure to the memory cells of the non-volatile memory cell arrangement 100. By applying suitable voltages, the charge in the traps of the memory cells can be neutralized. For example, in a charge trapping memory cell, the charge distribution in the charge trapping layer can be reset to a default state by applying voltages necessary for obtaining a negative gate voltage stress.

As the size of a non-volatile memory becomes larger, different memory cell sectors 104, 106, 108, 110, 112 and 114 of the non-volatile memory cell arrangement 100 can be used for different purposes depending on a quality class of particular memory cell sectors 104, 106, 108, 110, 112 and 114. The term quality class is used to classify the purposes for which the memory cells of the respective memory cell sectors 104, 106, 108, 110, 112 and 114 may be used. The quality classes can be, for example, a data storage reliability class, a data storage speed class, and a data storage multilevel capability class. In other words, at least some of the memory cell sectors 104, 106, 108, 110, 112 and 114 or all memory cell sectors 104, 106, 108, 110, 112 and 114 are assigned to one or more quality class segments, thereby characterizing the memory cells that are included in the respective memory cell sector 104, 106, 108, 110, 112 and 114, e.g., with respect to their data storage speed capability (e.g., represented by a data storage speed class), e.g., how fast data can be written to or read from the memory cells of the memory cell sector, with respect to the data storage reliability (e.g., represented by a data storage reliability class), e.g., how reliable the data can be stored and distinguished in the memory cells of the memory cell sector, or e.g., with respect to a data storage multilevel capability (e.g., represented by a data storage multilevel capability class), e.g., whether a plurality of bits (e.g., 2, 3, 4, etc.) can be stored in each memory cell of the memory cells of the memory cell sector 104, 106, 108, 110, 112 and 114. In other words, in the context used here, the term data storage multilevel capability class refers to multilevel data storage capability. Memory cell sectors 104, 106, 108, 110, 112 and 114 that are found to be members of a data storage multilevel capability class segment enabling multilevel storage can be used as multilevel memory cells.

Memory cell sectors 104, 106, 108, 110, 112 and 114 that are found to be members of a data storage reliability class segment with an acceptably high reliability can be used for archiving purposes. Memory cell sectors 104, 106, 108, 110, 112 and 114 that are found to be members of a data storage speed class segment with an acceptably high speed can be used for a cache memory. Memory cell sectors 104, 106, 108, 110, 112 and 114 that are members of more than one of the quality classes can be used for certain purposes as well. For example, memory cell sectors 104, 106, 108, 110, 112 and 114 can be found that are members of a certain data storage speed class segment and of a certain data storage reliability class segment. Memory cell sectors 104, 106, 108, 110, 112 and 114 that are not in one of the most reliable data storage reliability class segment(s) or in one of the faster data storage speed quality class segment(s) can be used to store user data.

Each of the trap neutralizing processes can be configured depending on the quality class of the memory cell sector(s) 104, 106, 108, 110, 112 and 114 to which the trap neutralizing process will be applied. For example, each of the trap neutralizing processes can be configured depending on the data storage multilevel capability class segment or the number of bits per memory cell that will be stored in the memory cell sector(s) 104, 106, 108, 110, 112 and 114 to which the trap neutralizing process will be applied.

At 204, after having received a programming instruction e.g. via the command interface CMD and the address interface ADD, the controller 122 selects one memory cell sector 104, 106, 108, 110, 112 and 114 out of a plurality of memory cell sectors 104, 106, 108, 110, 112 and 114.

Then, at 206, the controller 122 determines, whether the memory cells of the selected memory cell sector 104, 106, 108, 110, 112 and 114 has been neutralized in accordance with a predefined program neutralizing process.

If the memory cells of the selected memory cell sector 104, 106, 108, 110, 112 and 114 have been neutralized in accordance with the predefined program neutralizing process, at 208, one or more memory cells of the selected memory cell sector 104, 106, 108, 110, 112 and 114 are programmed (written) in accordance with the received programming instruction.

If the memory cells of the selected memory cell sector 104, 106, 108, 110, 112 and 114 have not been neutralized in accordance with the predefined program neutralizing process, at 210, the memory cells of the selected memory cell sector 104, 106, 108, 110, 112 and 114 are neutralized in accordance with a selected program neutralizing process.

Next, at 212, one or more memory cells of the selected and neutralized memory cell sector 104, 106, 108, 110, 112 and 114 are programmed (written) in accordance to the received programming instruction.

FIG. 3 shows a flowchart of another exemplary embodiment of a method 300 of programming a non-volatile memory, which shows an increased endurance compared to the conventional method.

Processes 202 to 208 are identical to the embodiment shown in FIG. 2 and will therefore not be explained again.

However, in case that the memory cells of the selected memory cell sector 104, 106, 108, 110, 112 and 114 have not been neutralized in accordance with the predefined program neutralizing process, at 302, a further memory cell sector of the plurality of memory cell sectors 104, 106, 108, 110, 112 and 114 is selected.

At 304, the controller 122 determines, whether the memory cells of the selected further memory cell sector 104, 106, 108, 110, 112 and 114 has been neutralized in accordance with the predefined program neutralizing process.

If the memory cells of the selected further memory cell sector 104, 106, 108, 110, 112 and 114 have been neutralized in accordance with the predefined program neutralizing process, at 306, one or more memory cells of the selected memory cell sector 104, 106, 108, 110, 112 and 114 are programmed (written) in accordance to the received programming instruction.

If the memory cells of the selected further memory cell sector 104, 106, 108, 110, 112 and 114 have not been neutralized in accordance with the predefined program neutralizing process, the process continues at 302, in which a yet further memory cell sector of the plurality of memory cell sectors 104, 106, 108, 110, 112 and 114 is selected. This process continues until either a suitable memory cell sector 104, 106, 108, 110, 112 and 114 could be determined or all available memory cell sectors 104, 106, 108, 110, 112 and 114 have been checked. In case no memory cell sector 104, 106, 108, 110, 112 and 114 could be determined, the memory cells of which have been neutralized in accordance with the predefined program neutralizing process, either one or a plurality of the memory cell sectors 104, 106, 108, 110, 112 and 114 are neutralized in accordance with a selected program neutralizing process (followed by a programming of the suitably neutralized memory cells) or an error message is generated indicating that it was not possible to carry out the programming process (not shown in FIG. 3).

In all embodiments of the invention, the endurance of the memory cells is increased by applying one trap-neutralizing process of a plurality of different types of trap-neutralizing processes to the plurality of memory cell sectors 104, 106, 108, 110, 112 and 114 of the non-volatile memory cell arrangement 100. In one embodiment of the invention, each of the plurality of trap-neutralizing processes is dependent on a quality class of a respective group of the plurality of memory cell sectors 104, 106, 108, 110, 112 and 114 and neutralizes a plurality of charges from a plurality of traps in the memory cells of the plurality of memory cell sectors 104, 106, 108, 110, 112 and 114. The plurality of charges could be neutralized by being freed from the plurality of traps. The trap-neutralizing methods could be configured to inherently erase the memory cell sectors 104, 106, 108, 110, 112 and 114 to which the trap neutralizing process is applied, or a program neutralizing procedure could be additionally performed either before or after the trap-neutralizing process so that the sector(s) is ready to be programmed.

For example, consider an NROM (nitride read only memory) as an example of a charge trapping memory cell arrangement having a plurality of memory cell sectors included in different multilevel data storage capability quality classes.

Consider multilevel data storage capability quality class segments of memory cells having a data storage capability of 1 bit/cell, 2 bits/cell, 4 bits/cell, and 6 bits/cell, for example.

The trap neutralizing process used for the memory cell sectors in the 1 bit/cell multilevel data storage capability quality class segment could be a fast single pulse HH (hot hole) erase. Furthermore, a PAE (program after erase) could then be performed on these memory cell sectors.

The trap-neutralizing process used for the memory cell sectors in the 2 bit/cell multilevel data storage capability quality class segment could be a two pulse HH (hot hole) erase with sparse PBE (program before erase). A PAE (program after erase) could then be performed on these memory cell sectors.

The trap neutralizing process used for the memory cell sectors in the 4 bit/cell multilevel data storage capability quality class segment could be an electrical refresh method that will be described in more detail with reference to FIG. 4. The trap neutralizing method used for the memory cell sectors in the 6 bit/cell multilevel data storage capability quality class segment could create an ultra small threshold voltage distribution (Vt distribution) in the charge trapping layer. The invention should not be construed as being limited to use with a memory configured from NROM cells as this descriptive portion has merely been given as one example.

As shown in a flow diagram 400 in FIG. 4, at 402, a neutralizing pulse is applied to the memory cells of the memory cell sector to be neutralized at a predetermined erase voltage, e.g. of 1.5 V, 3 V, 5 V. In general, the neutralizing pulse is applied to the memory cells of the memory cell sector to be neutralized in accordance with the selected trap neutralizing method (in general in accordance with the selected program neutralizing method).

Furthermore, at 404, it is determined whether the neutralizing has already been successful. This determination may be carried out by measuring the threshold voltage of the memory cells of the memory cell sector to be neutralized and by comparing it with a predetermined neutralizing threshold voltage that represents a minimum threshold voltage a memory cell has to have to be classified as neutralized.

If it has been determined in 404 that the neutralizing has not yet been successful (“No” in 404), it is determined at 406 whether the maximum allowable neutralizing voltage has been applied in the previous neutralizing pulse at 402. If the maximum allowable neutralizing voltage has been applied in the previous neutralizing pulse at 402 (“Yes” in 406), at 408, the memory cells are refreshed (e.g., the method to refresh the storage layer is based on applying a negative voltage to the gate (high negative voltages, e.g. >−10V, a moderate negative voltage to the bulk and a slightly positive voltage to source and drain) and another neutralizing pulse is applied to the memory cells of the memory cell sector to be neutralized at the predetermined neutralizing voltage, in other words, the method continues at 402. If the maximum allowable neutralizing voltage has not been applied in the previous neutralizing pulse at 402 (“No” in 406), at 410, the neutralizing voltage is increase by a predetermined amount (e.g. in a step-wise manner, in each step (iteration) by a predetermined amount, e.g., by 100 mV) and another neutralizing pulse is applied to the memory cells of the memory cell sector to be neutralized at the increased neutralizing voltage, in other words, the method continues at 402 with the increased neutralizing voltage.

If it has been determined in 404 that the neutralizing has been successful (“Yes” in 404), a predetermined number of dummy program/neutralizing cycles are carried out (e.g., 100, 200, 300, 500, 1000, etc.). Then, the neutralizing process is completed.

The memory cell sector table 102 is used to keep track of which type of trap-neutralizing process is performed on each memory cell sector as previously illustrated.

Before programming a memory cell sector, the memory cell sector table 120 is checked to determine whether a trap-neutralizing method has been performed on the memory cell sector with acceptable success (which may be represented by the information about which trap-neutralizing method (in general, which program neutralizing method) has been carried out on the memory cells of the memory cell sector). For example, if a multiple number of bits/cell is going to be stored in the memory cells of a memory cell sector, it is determined whether the trap-neutralizing method performed on the memory cell sector (indicated in the memory cell sector table 120) is of a type that is sufficient to neutralize the charge in the traps of the memory cells of this specific memory cell sector.

Taking the case of the NROM as a more specific example, if 1 bit/cell is going to be stored in the memory cell sector, it is determined whether a fast single pulse HH (hot hole) erase was previously performed on the sector, or whether another type of trap-neutralizing method was previously performed on the sector. If an acceptable type of trap-neutralizing method was performed on the memory cells of the memory cell sector, the memory cell sector can be programmed (see, e.g., 208 in FIG. 2 and FIG. 3).

If a trap-neutralizing method has not been performed on the memory cell sector with acceptable success, then, as described above, additional steps are provided to insure that the memory cells of the memory cell sector to be programmed has undergone a trap-neutralizing process with acceptable success before being programmed.

As described above, in an embodiment of the invention, a trap-neutralizing process is carried with acceptable success out on the memory cells of the memory cell sector so that the memory cells of the memory cell sector can be subsequently programmed as indicated in 212 in FIG. 2.

In another embodiment of the invention, a searching for an erased memory cell sector that has undergone a trap-neutralizing process with acceptable success is provided. The memory cell sector found in the search can be subsequently programmed as indicated in 306 in FIG. 3.

In accordance with one embodiment of the invention, in the beginning of the methods, the type of data to be stored is determined and, using a table, in which for a plurality of different types of data (e.g., computer program code or use data (e.g., content such as video data, audio data, etc.) assigned program neutralizing methods are stored, which a memory sector should have undergone before the respective type of data are allowed to be stored in the respective memory cell or memory cell sector, one or a plurality of suitable memory cell sector(s) is/are determined in accordance with a method described above.

In one embodiment of the invention, a memory cell arrangement is provided that decouples endurance and retention by means of a special erase procedure which refreshes the accumulation of charge in the nitride and damage in the bottom oxide.

In one embodiment of the invention, a method of programming a memory cell is provided, including determining, whether the memory cell has been neutralized in accordance with a predefined program neutralizing process, if the memory cell has not been neutralized in accordance with the predefined program neutralizing process. The method further includes neutralizing the memory cell in accordance with a selected program neutralizing process, and programming the memory cell.

In another embodiment of the invention, a method of programming a memory cell is provided, including determining, whether the memory cell has been neutralized in accordance with a predefined program neutralizing process. If the memory cell has been neutralized in accordance with the predefined program neutralizing process, the memory cell is programmed. If the memory cell has not been neutralized in accordance with the predefined program neutralizing process, a further memory cell is selected and it is determined, whether the further memory cell has neutralized in accordance with the predefined program neutralizing process. If the further memory cell has been neutralized in accordance with the predefined program neutralizing process, the further memory cell is programmed.

In accordance with one embodiment of the invention, the determination, whether the memory cell has been neutralized in accordance with the predefined program neutralizing process includes determining, whether the memory cells of a memory cell sector, which includes the memory cell, have been neutralized in accordance with the predefined program neutralizing process.

In accordance with one embodiment of the invention, the determination, whether the selected memory cell been neutralized in accordance with a predefined program neutralizing process includes reading a memory cell program neutralizing status information from a program neutralizing status table which includes the information, assigned for each one of a plurality of memory cells sectors, with which program neutralizing process the memory cells of the respective memory cell sector has been neutralized, and determining, whether the program neutralizing process identified by the memory cell program neutralizing status information for the selected memory cell sector meets with a predetermined program neutralizing process.

In accordance with one embodiment of the invention, the determining, whether the memory cells of the memory cell sector have been neutralized in accordance with a predefined program neutralizing process includes reading a memory cell sector program neutralizing status information from a program neutralizing status table which includes the information, assigned for each one of a plurality of memory cell sectors, with which program neutralizing process the memory cells of the respective memory cell sector have been neutralized, and determining, whether the program neutralizing process identified by the memory cell sector program neutralizing status information for the selected memory cell sector meets with a predetermined program neutralizing process.

The memory cell may be a non-volatile memory cell, e.g., a floating gate memory cell, e.g., a multi-bit floating gate memory cell. Furthermore, the non-volatile memory cell may be a charge trapping memory cell, e.g., a multi-bit charge trapping memory cell.

In one embodiment of the invention, each program neutralizing process is a trap-neutralizing process.

In one embodiment of the invention, if the memory cell has not been neutralized, a program neutralizing process out of a plurality of program neutralizing processes is selected and the memory cell is neutralized in accordance with the selected program neutralizing process.

In one embodiment of the invention, the method may further include classifying each memory cell sector into at least one quality class segment of a plurality of quality class segments of at least one quality class, the predefined erase process being dependent on the quality class segment, the memory cell sector is classified into.

In one embodiment of the invention, each one of the plurality of quality classes may be selected from a group of quality classes consisting of a data storage speed class, a data storage reliability class, and a data storage multilevel capability class.

In one embodiment of the invention, a memory cell arrangement is provided including a plurality of memory cells, a determination unit determining, whether a memory cell to be programmed has been neutralized in accordance with a predefined program neutralizing process, a controller controlling programming and neutralizing of the memory cells, being configured to neutralize the memory cell in accordance with a selected program neutralizing process, if the memory cell has not been neutralized in accordance with a predefined program neutralizing process, and to program the memory cell.

In another embodiment of the invention, a memory cell arrangement is provided including a plurality of memory cells, a determination unit determining, whether a memory cell to be programmed has been neutralized in accordance with a predefined program neutralizing process, a controller controlling programming and neutralizing of the memory cells, being configured to program the memory cell, if the memory cell has been neutralized in accordance with the predefined program neutralizing process, and to select a further memory cell, if the memory cell has not been neutralized in accordance with the predefined program neutralizing process, and to determine, whether the further memory cell has been neutralized in accordance with the predefined program neutralizing process, and programming the further memory cell, if the further memory cell has been neutralized in accordance with the predefined program neutralizing process.

Furthermore, a program neutralizing process memory may be provided storing a plurality of program neutralizing processes.

The memory cells may be non-volatile memory cells, e.g. floating gate memory cells, e.g. multi-bit floating gate memory cells or multi-level floating gate memory cells. Furthermore, the non-volatile memory cells may be charge trapping memory cells, e.g., multi-bit charge trapping memory cells or multi-level charge trapping memory cells.

Each erase process may be a trap-neutralizing process.

In another embodiment of the invention, a memory cell arrangement is provided including a plurality of memory cells, a determination unit determining, whether a memory cell to be programmed has been neutralized in accordance with a predefined program neutralizing process, a controller controlling programming and neutralizing of the memory cells, and a program neutralizing circuit neutralizing the memory cell in accordance with a selected program neutralizing process, if the memory cell has not been neutralized in accordance with a predefined program neutralizing process.

In one embodiment of the invention, a method of programming a memory cell is provided that includes determining, whether the memory cell has been neutralized in accordance with a predefined program neutralizing criterion, if the memory cell has not been neutralized in accordance with the predefined program neutralizing criterion, neutralizing the memory cell in accordance with a selected program neutralizing process, and programming the memory cell.

In one embodiment of the invention, a method of programming a memory cell is provided that includes determining, whether the memory cell has been neutralized in accordance with a predefined program neutralizing criterion, if the memory cell has been neutralized in accordance with the predefined program neutralizing criterion, programming the memory cell, if the memory cell has not been neutralized in accordance with the predefined program neutralizing process, selecting a further memory cell and determining, whether the further memory cell has been neutralized in accordance with the predefined program neutralizing criterion, and if the further memory cell has been neutralized in accordance with the predefined program neutralizing criterion, programming the further memory cell.

The predefined program neutralizing criterion may be a predefined program neutralizing level.

In one embodiment of the invention, a memory cell arrangement is provided that includes a plurality of memory cells, a determination unit determining, whether a memory cell to be programmed has been neutralized in accordance with a predefined program neutralizing criterion, a controller controlling programming and neutralizing of the memory cells, being configured to neutralizing the memory cell in accordance with a selected program neutralizing process, if the memory cell has not been neutralized in accordance with the predefined program neutralizing criterion, and program the memory cell.

In one embodiment of the invention, a memory cell arrangement is provided that includes a plurality of memory cells, a determination unit determining, whether a memory cell to be programmed has been neutralized in accordance with a predefined program neutralizing criterion, a controller controlling programming and neutralizing of the memory cells, being configured to program the memory cell, if the memory cell has been neutralized in accordance with the predefined program neutralizing criterion, select a further memory cell, if the memory cell has not been neutralized in accordance with the predefined program neutralizing criterion, and to determine, whether the further memory cell has been neutralized in accordance with the predefined program neutralizing criterion, and programming the further memory cell, if the further memory cell has been neutralized in accordance with the predefined program neutralizing criterion.

It should be appreciated by those skilled in the art, that the described processes may be implemented in hardware, software, firmware or a combination of these implementations as appropriate. For example, the operation of selecting a memory cell may be carried out by word and bit-line decoders under the control of an I/O interface unit such as a computer. Accordingly, the described operations may be implemented as executable instructions stored on a computer readable medium (removable disk, volatile or non-volatile memory, embedded processors, etc.), the stored instruction code operable to program a computer of other such programmable device to carry out the intended functions.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A method of programming a memory cell, comprising:
determining whether the memory cell has been neutralized in accordance with a predefined program neutralizing process, the predefined neutralizing process being one out of a plurality of program neutralizing processes;
if the memory cell has not been neutralized in accordance with a predefined program neutralizing process, neutralizing the memory cell in accordance with a selected program neutralizing process; and
programming the memory cell.

2. The method of claim 1, wherein determining whether the memory cell has been neutralized in accordance with the predefined program neutralizing process comprises determining whether memory cells of a memory cell sector that includes the memory cell, have been neutralized in accordance with the predefined erase process.

3. The method of claim 1, wherein determining whether the selected memory cell has been neutralized in accordance with a predefined program neutralizing process comprises:
reading a memory cell program neutralizing status information from a program neutralizing status table which includes the information, assigned for each one of a plurality of memory cells sectors, with which program neutralizing process the memory cells of the respective memory cell sector has been neutralized; and
determining whether the program neutralizing process identified by the memory cell program neutralizing status information for the selected memory cell sector meets with a predetermined program neutralizing process.

4. The method of claim 3, wherein determining whether the memory cells of the memory cell sector have been neutralized in accordance with the predefined erase process comprises:
reading a memory cell sector program neutralizing status information from a program neutralizing status table which includes the information, assigned for each one of a plurality of memory cell sectors, with which program neutralizing process the memory cells of the respective memory cell sector have been neutralized; and
determining, whether the program neutralizing process identified by the memory cell sector program neutralizing status information for the selected memory cell sector meets with a predetermined program neutralizing process.

5. The method of claim 1, wherein the memory cell comprises a non-volatile memory cell.

6. The method of claim 1, wherein the memory cell comprises a floating gate memory cell.

7. The method of claim 6, wherein the memory cell comprises a multi-bit floating gate memory cell or multi-level floating gate memory cell.

8. The method of claim 1, wherein the memory cell comprises a charge trapping memory cell.

9. The method of claim 8, the memory cell being a multi-bit charge trapping memory cell or a multi-level charge trapping memory cell.

10. The method of claim 8, wherein each program neutralizing process comprises a trap-neutralizing process.

11. The method of claim 1, wherein, if the memory cell has not been neutralizing, selecting a program neutralizing process out of a plurality of program neutralizing processes, and neutralizing the memory cell in accordance with the selected program neutralizing process.

12. The method of claim 11, further comprising classifying each memory cell sector into at least one quality class segment of a plurality of quality class segments of at least one quality class, the predefined erase process being dependent on the quality class segment the memory cell sector is classified into.

13. The method of claim 12, wherein each one of the plurality of quality classes is a quality class selected from the group consisting of a data storage speed class, a data storage reliability class, and a data storage multilevel capability class.

14. A method of programming a memory cell, comprising:
determining whether the memory cell has been neutralized in accordance with a predefined program neutralizing process;
if the memory cell has been neutralized in accordance with the predefined program neutralizing process, programming the memory cell;
if the memory cell has not been neutralized in accordance with the predefined program neutralizing process, selecting a further memory cell and determining whether the further memory cell has been neutralized in accordance with the predefined program neutralizing process; and
if the further memory cell has been neutralized in accordance with the predefined program neutralizing process, programming the further memory cell.

15. A memory cell arrangement, comprising:
a plurality of memory cells;
a determination unit determining whether a memory cell to be programmed has been neutralized in accordance with a predefined program neutralizing process;
a controller controlling programming and neutralizing of the memory cells, the controller being configured to neutralize the memory cell in accordance with a selected program neutralizing process, if the memory cell has not been neutralized in accordance with a predefined program neutralizing process.

16. The memory cell arrangement of claim 15, further comprising a program neutralizing process memory storing a plurality of program neutralizing processes.

17. The memory cell arrangement of claim 15, wherein the memory cells comprise non-volatile memory cells.

18. The memory cell arrangement of claim 17, wherein the memory cells comprise floating gate memory cells.

19. The memory cell arrangement of claim 17, wherein the memory cells comprise multi-bit floating gate memory cells or multi-level floating gate memory cells.

20. The memory cell arrangement of claim 17, wherein the memory cells comprise charge trapping memory cells.

21. The memory cell arrangement of claim 20, wherein the memory cells comprise multi-bit charge trapping memory cells or multi-level charge trapping memory cells.

22. The memory cell arrangement of claim 21, wherein each program neutralizing process comprises a trap-neutralizing process.

23. A memory cell arrangement, comprising:
a plurality of memory cells;
a determination unit determining whether a memory cell to be programmed has been neutralized in accordance with a predefined program neutralizing process;
a controller controlling programming and neutralizing of the memory cells, the controller being configured to program the memory cell, if the memory cell has been neutralized in accordance with the predefined program neutralizing process, to select a further memory cell, if the memory cell has not been neutralized in accordance with the predefined program neutralizing process, and to determine whether the further memory cell has been neutralized in accordance with the predefined program neutralizing process, and cause the further memory cell to be programmed if the further memory cell has been neutralized in accordance with the predefined program neutralizing process.

24. A memory cell arrangement, comprising:
a plurality of memory cells;
a determination unit determining whether a memory cell to be programmed has been neutralized in accordance with a predefined program neutralizing process;
a controller controlling programming and neutralizing of the memory cells, and
a neutralizing circuit neutralizing the memory cell in accordance with a selected program neutralizing process, if the memory cell has not been neutralized in accordance with a predefined program neutralizing process.

25. A method of programming a memory cell, comprising:
determining whether the memory cell has been neutralized in accordance with a predefined program neutralizing criterion;
if the memory cell has not been neutralized in accordance with the predefined program neutralizing criterion, neutralizing the memory cell in accordance with a selected program neutralizing process; and
programming the memory cell.

26. The method of claim 25, wherein the predefined program neutralizing criterion is a predefined program neutralizing level.

27. A method of programming a memory cell, the method comprising:
determining whether the memory cell has been neutralized in accordance with a predefined program neutralizing criterion;
if the memory cell has been neutralized in accordance with the predefined program neutralizing criterion, programming the memory cell;
if the memory cell has not been neutralized in accordance with the predefined program neutralizing process, selecting a further memory cell and determining whether the further memory cell has been neutralized in accordance with the predefined program neutralizing criterion; and
if the further memory cell has been neutralized in accordance with the predefined program neutralizing criterion, programming the further memory cell.

28. The method of claim 27, wherein the predefined program neutralizing criterion is a predefined program neutralizing level.

29. A memory cell arrangement, comprising:
a plurality of memory cells;
a determination unit determining whether a memory cell to be programmed has been neutralized in accordance with a predefined program neutralizing criterion;
a controller controlling programming and neutralizing of the memory cells, being configured to neutralize the memory cell in accordance with a selected program neutralizing process and, if the memory cell has not been neutralized in accordance with the predefined program neutralizing criterion, program the memory cell.

30. A memory cell arrangement, comprising:
a plurality of memory cells;
a determination unit determining whether a memory cell to be programmed has been neutralized in accordance with a predefined program neutralizing criterion;
a controller controlling programming and neutralizing of the memory cells, being configured to
program the memory cell, if the memory cell has been neutralized in accordance with the predefined program neutralizing criterion;
select a further memory cell, if the memory cell has not been neutralized in accordance with the predefined program neutralizing criterion, and to determine, whether the further memory cell has been neutralized in accordance with the predefined program neutralizing criterion, and programming the further memory cell, if the further memory cell has been neutralized in accordance with the predefined program neutralizing criterion.

31. The memory cell arrangement of claim 30, wherein the predefined program neutralizing criterion is a predefined program neutralizing level.
